(19) United States
(12) Patent Application Publication
(10) Pub. No.: US 2009/0127711 A1
(43) Pub. Date: May 21, 2009

(54) INTERCONNECT STRUCTURE AND METHOD OF MAKING SAME

(75) Inventors: Griselda Bonilla, Fishkill, NY (US); Daniel C. Edelstein, White Plains, NY (US); Mahadevaiyer Krishnan, Hopewell Junction, NY (US); Takeshi Nogami, Schenectady, NY (US); David L. Rath, Stormville, NY (US)

Correspondence Address: GREENBLUM & BERNSTEIN, P.L.C., 1950 ROLAND CLARKE PLACE, RESTON, VA, 20191, US

(73) Assignee: INTERNATIONAL BUSINESS MACHINES CORPORATION, ARMONK, NY (US)

(21) Appl. No.: 11/940,487

(22) Filed: Nov. 15, 2007

(51) Int. Cl. H01L 23/48; H01L 21/4763

(52) U.S. Cl. 257/758; 438/625; 257/E23.01; 257/E21.495

(57) ABSTRACT

A highly reliable copper interconnect structure and method of fabricating the same is provided. The interconnect structure comprises a metal layer buried between an adjacent upper copper layer and an adjacent lower copper layer structure. More specifically, the interconnect structure comprises a recess formed in a dielectric layer; a barrier metal lining sidewalls of the recess; a first copper layer within the recess; a second copper layer within the recess; and a metal layer buried between the first copper layer and the second copper layer. The method comprises forming a recess in an interlayer dielectric; forming a first copper layer, a metal layer over the first copper layer and a second copper layer over the metal layer, all within the recess. The metal layer is sandwiched between the first copper layer and the second copper layer within the recess.

### FIELD OF THE INVENTION

The present invention relates generally to an interconnect structure and method of fabricating the same and, more particularly, to a highly reliable copper interconnect structure and method of fabricating the same.

### BACKGROUND OF THE INVENTION

Electromigration is the transport of material caused by the gradual movement of ions in a conductor due to the momentum transfer between conducting electrons and diffusing metal atoms. The effect of electromigration is an important consideration to take into account in applications where high direct current densities are used, such as in microelectronics and related structures. In fact, electromigration is known to decrease the reliability of integrated circuits (ICs) and hence lead to a malfunction of the circuit. In the worst case, for example, electromigration leads to the eventual loss of one or more connections and intermittent failure of the entire circuit.

The effect of electromigration becomes an increasing concern as the size of the IC decreases. That is, as the structure size in ICs decreases, the practical significance of this effect increases. Thus, with increasing miniaturization the probability of failure due to electromigration increases in VLSI and ULSI circuits because both the power density and the current density increase.

In advanced semiconductor manufacturing processes, copper is used as the interconnect material. Basically, copper is preferred for its superior conductivity. However, copper interconnects have been facing the limitation of the electromigration lifetime or the upper limitation of the current density because of electromigration failure. To solve this problem, though, capping copper interconnects with CoWP or CoWB has been widely investigated. It has been found that the copper interconnects can have higher electromigration resistance when capped with CoWP or CoWB, because the top surface of the copper interconnects is the most susceptible electromigration void nucleation site.

However, the CoWP or CoWB capping has problems that hamper its application to manufacturing. For example, a problem lies in the line-to-line leakage, which is caused by the presence of cobalt atoms on the surface of an interlayer dielectric between the copper interconnects. Since the distance between the neighboring copper lines is becoming smaller as the device shrinks, the line-to-line leakage with the CoWP or CoWB capped interconnects is becoming more serious. The difficulty of this problem lies in the situation that, when some process steps to remove cobalt atoms out of the dielectric surface is applied, the process removes the neighboring CoWP or CoWB surface at the same time and then, the removed cobalt atoms again adhere on the dielectric surface.

Accordingly, there exists a need in the art to overcome the deficiencies and limitations described hereinabove.

### SUMMARY OF THE INVENTION

In a first aspect of the invention an interconnect structure comprises a metal layer buried between an adjacent upper copper layer and an adjacent lower copper layer structure within a recess of an interlayer dielectric layer.

In another aspect of the invention, an interconnect structure comprises a recess formed in a dielectric layer; a barrier metal lining sidewalls of the recess; a first copper layer within the recess; a second copper layer within the recess; and a metal layer buried between the first copper layer and the second copper layer.

In another aspect of the invention, a method of forming an interconnect structure is provided. The method comprises forming a recess in an interlayer dielectric, forming a first copper layer, a metal layer over the first copper layer, and a second copper layer over the metal layer, all within the recess. The metal layer is sandwiched between the first copper layer and the second copper layer within the recess.

### BRIEF DESCRIPTION OF THE DRAWINGS

The present invention is described in the detailed description which follows, in reference to the noted plurality of drawings by way of non-limiting examples of exemplary embodiments of the present invention, in which:

FIGS. 1-6 show intermediate structures and respective fabrication processes in accordance with a first aspect of the invention;

FIG. 7 shows a final structure and accompanying fabrication processes in accordance with the first aspect of the invention;

FIGS. 8-13 show intermediate structures and respective fabrication processes in accordance with a second aspect of the invention; and

FIG. 14 shows a final structure and accompanying fabrication processes in accordance with the second aspect of the invention.

### DETAILED DESCRIPTION OF EMBODIMENTS OF THE INVENTION

The present invention relates generally to an interconnect structure and method of fabricating the same and, more particularly, to a highly reliable copper interconnect structure and method of fabricating the same. By implementing the fabrication processes in accordance with the invention, the copper interconnects do not have any undesirable cobalt on their top surface. Instead, cobalt atoms, which resided on the field area, e.g., on the barrier layer, are removed entirely by a chemical mechanical process, for example, together with copper and the underlying barrier materials.

Advantageously, by implementing the fabrication processes in accordance with the invention, the copper interconnect does not have any line-to-line leakage problems, which are typical of conventional CoWP capped copper interconnects. Instead, a metal layer such as a CoWP or CoWB layer is buried in the copper interconnect, e.g., the CoWP or CoWB layer is buried between an upper copper layer and a lower copper layer, which forms the interconnect; rather than being placed on top of the copper interconnect as in conventional systems. The redundant mechanism of the upper copper layer and the lower copper layer is the basis of the enhanced electromigration resistance of the CoWP or buried interconnect.

The copper interconnect with such a buried metal layer has higher electromigration resistance and lifetime. For example, when the copper atoms located at the upper side of the buried metal layer, e.g., CoWP, (at the interface with the upper copper layer) migrate to create voids, the voids are located in the area on the CoWP layer. In this way, even when the voids grow entirely across the cross-sectional area of the copper interconnect on the CoWP layer (at the interface with the upper copper layer), the copper interconnect as a system does not cause any disconnection failure, e.g., electromigration open failure, because the lower layer of the copper interconnect keeps the conductivity even after the complete disconnection at the upper layer. Similarly, even when the lower layer of the copper interconnect becomes disconnected due to electromigration, the interconnect system does not reach the open failure until the upper part of the interconnect reaches the entire disconnection due to electromigration.

Also, in embodiments, a via deep enough to penetrate the buried metal layer is effective for further improvement of the electromigration resistance of the copper interconnect system. This penetrated via structure ensures the electrical conductivity of the via to both the upper copper layer and the lower copper layer at the same time. Then, the abovementioned redundant mechanism works more effectively.

### First Aspect of the Invention

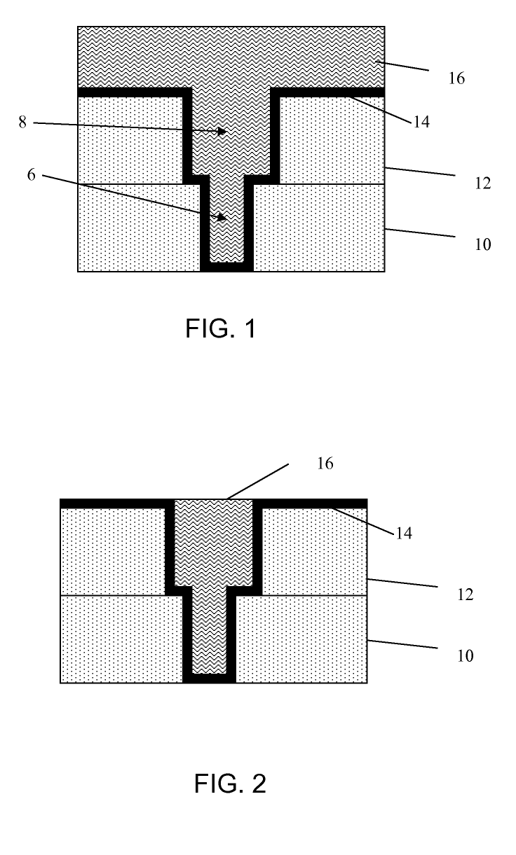

FIGS. 1-6 show intermediate structures and respective fabrication processes in accordance with a first aspect of the invention. FIG. 1 is a starting structure in accordance with a first aspect of the invention. FIG. 1 shows a structure having two dielectric layers 10, 12. In embodiments, the dielectric layers 10, 12 may be about 0.4 microns thick; although it should be understood that the thickness of the dielectric layers may vary depending on the particular application. In separate conventional lithographic processes, a via 6 is formed in the dielectric layer 10 and a trench 8 is formed in the dielectric layer 12. In embodiments, the diameter of the via 6 is about 0.5 microns and the width of the trench 8 is about 0.5 microns; although other dimensions are also contemplated by the invention.

A barrier metal layer 14 is formed over the dielectric layers 10, 12, including lined within the via 6 and trench 8. The barrier metal layer 14 may be, for example, tantalum or tantalum nitride, formed using a conventional physical vapor deposition (PVD) process. In embodiment, the thickness of the barrier metal layer 14 may be about 10 nm. A copper layer 16 is then formed over the entire structure, e.g., over the barrier metal layer 14, using a conventional electroplating process. The copper layer 16 may be about 1 micron thick, although other dimensions are further contemplated by the invention.

As shown in FIG. 2, the copper layer 16 is etched using a conventional process. For example, the copper layer 16 may be etched using a chemical mechanical polishing (CMP) process. The copper layer 16 is preferably etched to the barrier metal layer 14, thereby maintaining the barrier metal layer 14 over the surface of the dielectric layer 12.

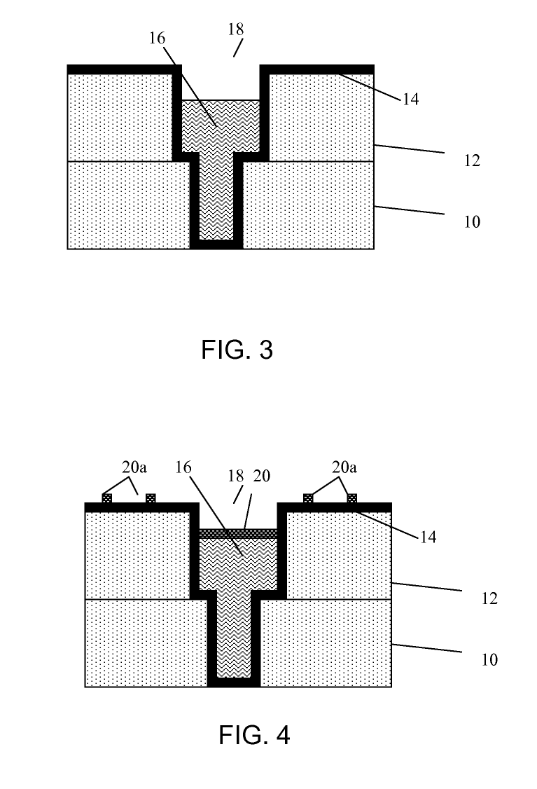

As shown in FIG. 3, the copper 16 is etched to form a recess 18 within the trench. The etching may be a conventional wet etch process to form the recess 18. In embodiments, the recess may be about 300 Å to 0.2 microns.

As shown in FIG. 4, a metal layer 20 such as, for example, CoWP or CoWB, is formed in the recess 18. The metal layer 20 may be formed using a conventional electroless plating process. Also, those of skill in the art should recognize that other metal layers can be formed in the recess such as, for example, Ru, Ta, and TaN (which eliminates undesirable cobalt atoms and hence eliminates line-to-line leakage). Basically any metal is contemplated by the invention which does not diffuse or substantially diffuse into copper. In this processing step, using cobalt, undesirable cobalt atoms 20a are formed on the barrier metal layer 14, above the dielectric layer 12.

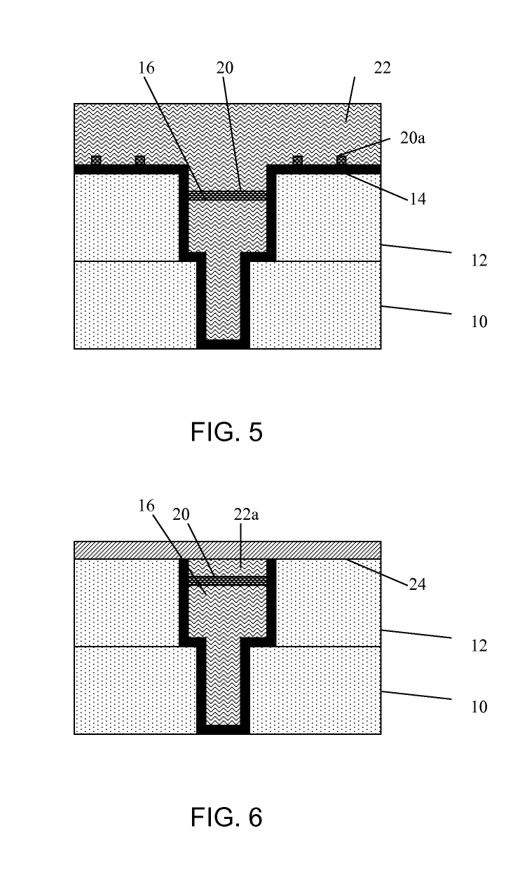

As shown in FIG. 5, a copper layer 22 is formed over the structure of FIG. 4. Specifically, in a first processing step, a copper seed layer is formed over the metal layer 20, undesirable cobalt atoms 20a and the barrier metal layer 14 using a conventional PVD process. In embodiments, the copper seed layer is between 120 Å to 1000 Å. The seed layer permits the subsequent formation of the copper layer 22, via the formation by a conventional electroplating process. The final height of the copper layer 22 is about 0.2 microns to 1 micron, in embodiments.

As shown in FIG. 6, the copper layer 22 and the barrier metal layer 14 are removed using a conventional CMP process, leaving an upper copper layer 22a within the recess. In this way, the metal layer 20 becomes sandwiched between the upper copper layer 22a and the lower copper layer 16, to provide the redundant interfaces for enhanced electromigration resistance of the CoWP or buried interconnect. As shown, now there is a metal to metal interface between the copper layers 22a and 16 with that of the metal layer 20.

As further shown in FIG. 6, a SiCN cap 24 is formed over the structure. More specifically, a SiCN cap 24 is formed over the dielectric layer 12 and upper copper layer 22a. The SiCN cap 24 acts as a diffusion barrier layer. The cap 24 may be any other known diffusion barrier layer. By using the cap 24, the copper will not diffuse out to the dielectric material formed in latter processing steps.

Also, as shown in FIG. 6, the structure of the invention provides a redundancy not found in conventional interconnect structures. For example, as discussed above, there is a metal to metal interface at both an upper and lower surface of the metal layer 20, e.g., copper and cobalt interface, which provides higher resistance to electromigration. As such, if any voids occur due to electromigration at one surface, the redundancy of the interconnect system will prevent a failure of the device.

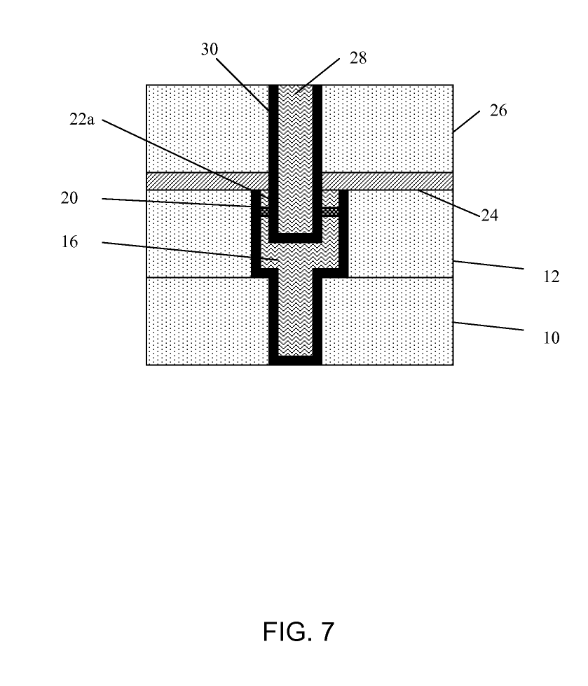

FIG. 7 shows a final structure and accompanying fabrication processes in accordance with the first aspect of the invention. As shown in FIG. 7, a dielectric layer 26 is formed over the structure formed in FIG. 6, in a conventional manner. A via is formed within the dielectric layer 26, penetrating through the upper copper layer 22a, the cap 24, the metal layer 20 and the lower copper layer 16. As such, the via is formed deeply into the underlying metal copper layer 16. The deep via is effective for further improvement of the electromigration resistance of the copper interconnect system as it ensures the electrical conductivity of the via to both the upper copper layer 22a and the lower copper layer 16 at the same time. A barrier metal 30 is formed on the sidewalls of the via and copper 28 is filled within the via.

In this configuration, advantageously, the metal layer 20, e.g., CoWP or CoWB, is buried between an upper copper layer 22a and a lower copper layer 16, which forms a redundant interconnect. In this way, the redundant mechanism of the upper copper layer 22a and the lower copper layer 16 is the basis of the enhanced electromigration resistance of the, e.g., CoWP, or buried interconnect. For example, when the copper atoms located at the upper side of the buried CoWP layer (at the interface with the upper copper layer 22a) migrate to create voids, the voids are located in the area on the CoWP layer 20. Accordingly, even when the voids grow entirely across the cross-sectional area of the copper interconnect on the CoWP layer (at the interface with the upper copper layer 22a), the copper interconnect as a system does not cause any disconnection failure, e.g., electromigration open failure, because the lower copper layer 16 keeps the conductivity even after the complete disconnection at the upper layer. Similarly, even when the lower copper layer 16 becomes disconnected due to electromigration, the interconnect system does not reach the open failure as the upper copper layer 22a will keep the conductivity.

### Second Aspect of the Invention

FIGS. 8-13 show intermediate structures and respective fabrication processes in accordance with a first aspect of the invention. Similar to the starting structure of FIG. 1, in FIG. 8 the starting structure includes two dielectric layers 10, 12. In embodiments, the dielectric layers 10, 12 may be about 0.4 microns thick; although it should be understood that the thickness of the dielectric layers may vary depending on the particular application. In separate conventional lithographic processes, a via 6 is formed in the dielectric layer 10 and a trench 8 is formed in the dielectric layer 12. In embodiments, the diameter of the via 6 is about 0.5 microns and the width of the trench 8 is about 0.5 microns; although other dimensions are also contemplated by the invention.

A barrier metal layer 14 is formed over the dielectric layers 10, 12, including lined within the via 6 and trench 8. The barrier metal layer 14 may be, for example, tantalum or tantalum nitride, formed using a conventional physical vapor deposition (PVD) process. In embodiment, the thickness of the barrier metal layer 14 may be about 10 nm. A copper layer 16 is then formed over the entire structure, e.g., over the barrier metal layer 14, using a conventional electroplating process. The copper layer 16 may be about 1 micron, although other dimensions are further contemplated by the invention.

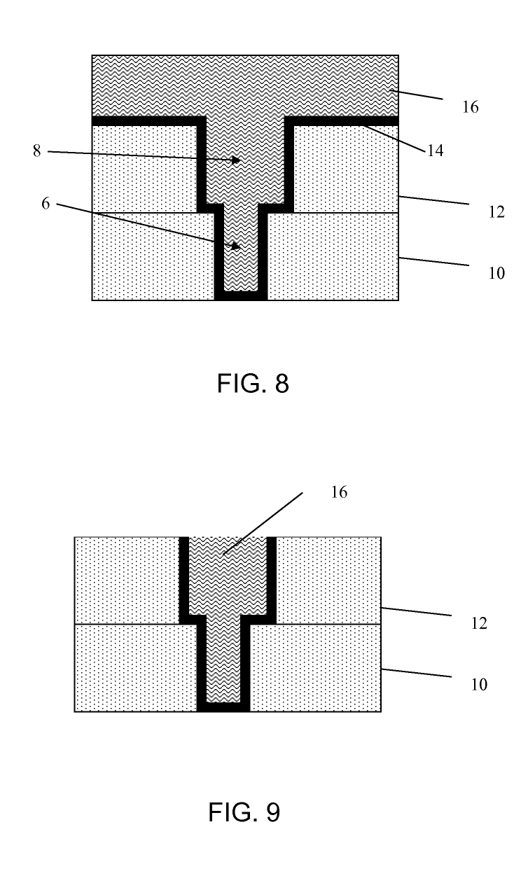

FIG. 9 shows an intermediate structure and respective fabrication processes in accordance with the invention. Similar to the starting structure of FIG. 2, in FIG. 9 the copper layer 16 is etched using a conventional process. For example, the copper layer 16 may be etched using a chemical mechanical polishing (CMP) process. The barrier metal layer 14 is subsequently etched using a chemical mechanical polishing (CMP) process.

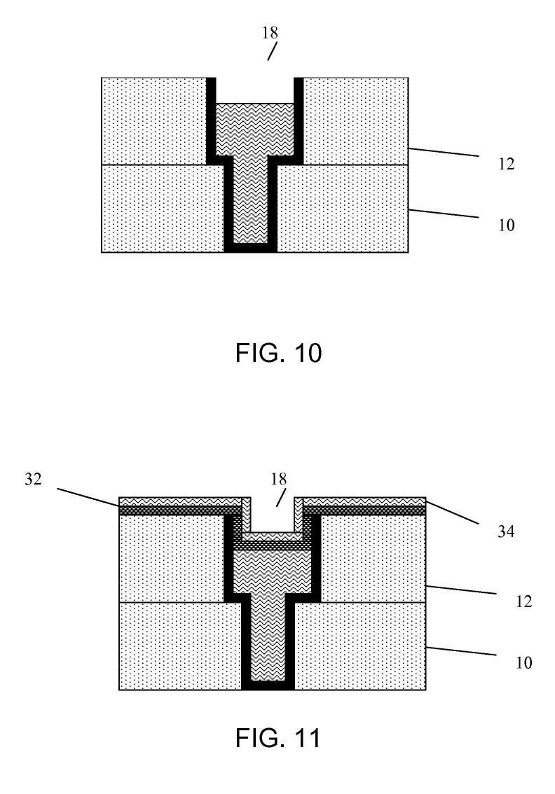

FIG. 10 shows an intermediate structure and respective fabrication processes in accordance with the invention. Similar to FIG. 3, as shown in FIG. 10, the copper layer 16 is etched to form a recess 18 within the trench. The etching may be a conventional wet etch process to form the recess 18. In embodiments, the recess may be about 300 Å to 0.2 microns.

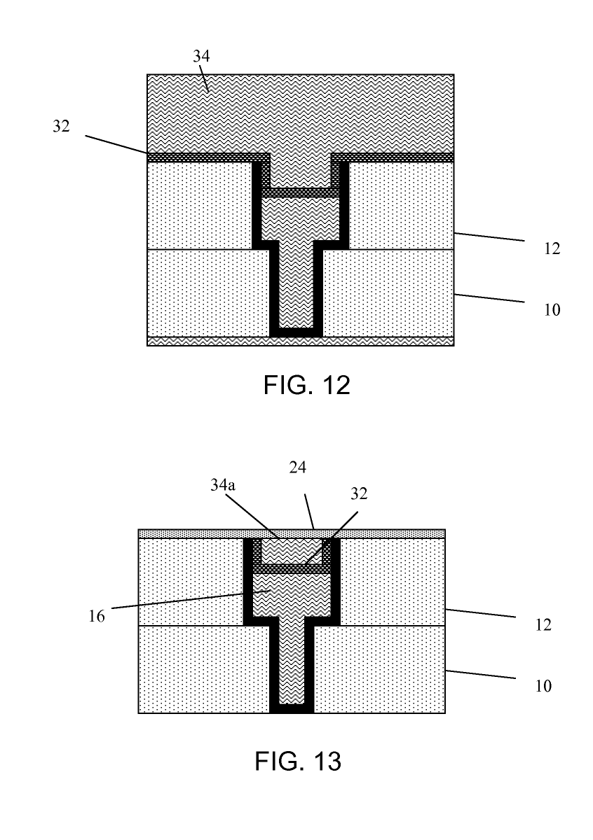

As shown in FIG. 11, a sputter pre-cleaning step is performed on the structure of FIG. 10. Thereafter, a metal layer 32 such as, for example, tantalum or Tantalum nitride, is formed in the recess 18 and over the dielectric layer 12. The metal layer 32 may be formed using a conventional PVD process. Also, those of skill in the art should recognize that other metal layers could also be formed in the recess such as, for example, ruthenium or cobalt.

A copper seed layer 34 is formed over the barrier metal layer 32. In embodiments, the copper seed layer is between 120 Å to 1000 Å. The seed layer permits the subsequent formation of a copper layer, via the formation by a conventional electroplating process.

As shown in FIG. 12, a copper layer also shown as reference numeral 34 is formed over the copper seed layer of FIG. 11. The final height of the copper layer 34 is about 0.2 microns to 1 micron, in embodiments.

FIG. 13 shows an intermediate structure and respective fabrication processes in accordance with the invention. As shown in FIG. 13, the copper layer 34 and the barrier metal layer 32 are removed using a conventional CMP process, leaving an upper copper layer 34a within the recess formed in the prior fabrication processes. In this way, the metal layer 32 becomes sandwiched between the upper copper layer 34a and the lower copper layer 16, to provide the redundant mechanism for enhanced electromigration resistance of the CoWP or buried interconnect.

As further shown in FIG. 13, a SiCN cap 24 is formed over the structure. More specifically, a SiCN cap 24 is formed over the dielectric layer 12 and upper copper layer 34a. The SiCN cap 24 acts as a diffusion barrier layer. The cap may be any other known diffusion barrier layer. By using the diffusion barrier layer, the copper will not diffuse out to the dielectric material formed in latter processing steps.

Also, as shown in FIG. 13, the structure of the invention provides a redundancy not found in conventional interconnect structures. For example, there is a metal to metal interface at both an upper and lower surface of the metal layer 32, e.g., copper and tantalum interface, which provides higher resistance to electromigration. As such, if any voids occur due to electromigration at one surface, the redundancy of the interconnect system will prevent a failure of the device.

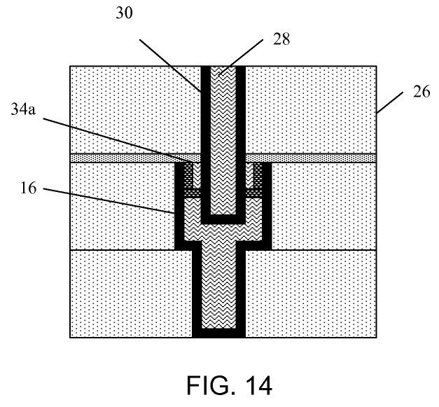

FIG. 14 shows a final structure and accompanying fabrication processes in accordance with the first aspect of the invention. As shown in FIG. 14, a dielectric layer 26 is formed over the structure formed in FIG. 13, in a conventional manner. A via is formed within the dielectric layer 26, penetrating through the upper copper layer 34a, the cap 24, the metal layer 32 and the lower copper layer 16. As such, the via is formed deeply into the underlying metal copper layer 16. The deep via is effective for further improvement of the electromigration resistance of the copper interconnect system as it ensures the electrical conductivity of the via to both the upper copper layer 34a and the lower copper layer 16 at the same time. A barrier metal 30 is formed on the sidewalls of the via and copper 28 is filled within the via.

In this configuration, advantageously, the metal layer 32 is buried between the upper copper layer 34a and the lower copper layer 16, which forms a redundant interconnect. In this way, the redundant mechanism of the upper copper layer 22a and the lower copper layer 16 is the basis of the enhanced electromigration resistance of the, e.g., tantalum, or buried interconnect. For example, when the copper atoms located at the upper side of the buried tantalum layer (at the interface with the upper copper layer 34a) migrate to create voids, the voids are located in the area on the metal layer 32. Accordingly, even when the voids grow entirely across the cross-sectional area of the copper interconnect on the tantalum layer (at the interface with the upper copper layer 34a), the copper interconnect as a system does not cause any disconnection failure, e.g., electromigration open failure, because the lower copper layer 20 keeps the conductivity even after the complete disconnection at the upper layer. Similarly, even when the lower copper layer 16 becomes disconnected due to electromigration, the interconnect system does not reach the open failure as the upper copper layer 22a will keep the conductivity.

The methods and structures as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with the structures of the invention) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

While the invention has been described in terms of embodiments, those skilled in the art will recognize that the invention can be practiced with modifications and in the spirit and scope of the appended claims.

1.-21. (canceled)

22. A method of forming an interconnect structure, comprising:
forming a trench in an interlayer dielectric layer;
lining the trench and the interlayer dielectric layer outside of the trench with a barrier Layer;
forming a first copper layer in the trench and over the barrier layer on the interlayer dielectric layer outside of the trench;
etching the first copper layer to expose the barrier layer outside of the trench and to further form a recess within the trench;
forming a metal layer of CoWP or CoWB over the first copper layer which leaves undesirable cobalt atoms on the exposed barrier layer outside of the trench;
forming a second copper layer over the metal layer and the exposed barrier layer, such that the metal layer is sandwiched between the first copper layer and the second copper layer within trench, overlaying the undesirable cobalt atoms;
removing the second copper layer, the undesirable cobalt atoms and the exposed barrier layer outside of the trench, leaving a portion of the second copper layer within the trench;
forming a cap layer over the interlayer dielectric layer and the portion of the second copper layer;
forming a dielectric layer on the interlayer dielectric layer and the portion of the second copper layer;
forming a via in the dielectric layer and penetrating through the first copper layer, the metal layer and the second copper layer; and
lining the via with a barrier layer and filling the via with copper.

23. The method of claim 22, wherein the cap is an SiCN cap.

24. The method of claim 23, wherein the SiCN cap is a diffusion barrier layer.

25. The method of claim 24, wherein the forming of the metal layer is an electroless process forming the undesirable cobalt atoms on the interlayer dielectric layer outside of the trench.

26. The method of claim 25, wherein the etching of the first copper layer exposes a portion of the barrier layer within the trench and forming the second copper layer contacts the exposed portion of the barrier layer in the trench.

27. A method of forming an interconnect structure, comprising:
forming a trench in an interlayer dielectric layer;
lining the trench and the interlayer dielectric layer outside of the trench with a barrier layer;
forming a first copper layer in the trench and over the barrier layer on the interlayer dielectric layer outside of the trench;
etching the first copper layer to expose the barrier layer outside of the trench and to form a recess within the trench;
subsequently etching the barrier layer outside of the trench to expose the interlayer dielectric layer outside of the trench,
forming a metal layer over the first copper layer and directly on the exposed barrier layer within the trench and the exposed interlayer dielectric layer outside of the trench;
forming a second copper layer over the metal layer such that the metal layer is sandwiched between the first copper layer and the second copper layer and adjacent the barrier layer within the trench;
removing the second copper layer and the metal layer over the interlayer dielectric layer outside of the trench; and
forming a cap layer over the interlayer dielectric layer and the second copper layer.
